(19) United States
(12) Patent Application Publication
(10) Pub. No.: US 2004/0079865 A1
(43) Pub. Date: Apr. 29, 2004

(54) Back side incident type image pickup sensor

(75) Inventor: Junichi Hoshi, Kanagawa (JP)

Correspondence Address: FITZPATRICK CELLA HARPER & SCINTO, 30 ROCKEFELLER PLAZA, NEW YORK, NY, 10112, US

(73) Assignee: Canon Kabushiki Kaisha, Tokyo (JP)

(21) Appl. No.: 10/673,289

(22) Filed: Sep. 30, 2003

(30) Foreign Application Priority Data
Oct. 9, 2002 (JP) 2002-296321

(51) Int. Cl. H01L 27/00; G01J 1/00; G01T 1/24

(52) U.S. Cl. 250/214.1; 250/370.08; 250/208.1

(57) ABSTRACT

A back side incident type image pickup sensor in which lowering of spatial resolution is eliminated and influence of stray light is removed is provided. Electric circuits including a driver circuit for driving a photoelectric conversion portion and a signal processing circuit for processing signals from the photoelectric conversion portion are each placed on the front side of a single crystal silicon substrate at a given distance in the horizontal direction from an opening. Influence of stray light is thus eliminated. The semiconductor substrate has high refractive index, thereby essentially allowing little lowering of spatial resolution. Lowering of spatial resolution is further prevented if the substrate is thinned.

### BACKGROUND OF THE INVENTION

1. Field of the Invention

The present invention relates to a back side incident type image pickup sensor for detecting an image using light that enters from the back side of a semiconductor substrate, and more specifically to a back side incident type image pickup sensor suitable as a fingerprint sensor or the like.

2. Related Background Art

CCD image pickup sensors are an example of conventional back side incident type image pickup sensors. A CCD image pickup sensor is formed on the front side of a single crystal silicon substrate and infrared light enters from the back side of the substrate for infrared image detection.

Application examples of infrared image pickup sensors include fingerprint sensors which have been the prevailing means of biometrics authentication in recent years. One of such fingerprint sensors is disclosed in Japanese Patent Application Laid-Open No. 2002-33469, for example. There are other image pickup sensors than those using visible light, and X-ray sensors provided with light-to-light conversion elements fall in this category. X-ray sensors are used to obtain transfer imaging of a human body, for example.

Back side incident type image pickup sensors have light-shielding structures such as grooves or apertures as disclosed in Japanese Patent Application Laid-Open No. 02-2688 or absorption belts as disclosed in Japanese Patent Application Laid-Open No. 05-206432.

However, conventional back side incident type image pickup sensors have problems given below.

(1) Semiconductor substrates used in conventional image pickup sensors are usually opaque.

(2) The substrate thickness is limited in back side incident type image pickup sensors and therefore the spatial resolution is lower than in front side incident type image pickup sensors.

(3) Back side incident type image pickup sensors are affected by stray light from the same reason as given in (2).

Sensors that are known to have Problem (1) above are CCD image pickup sensors described above as a prior art example, and only infrared light is used in the CCD image pickup sensors, which are conventional back side incident type image pickup sensors.

### SUMMARY OF THE INVENTION

The present invention has been made in view of the above-described problems of the prior arts, and an object of the present invention is therefore to provide a back side incident type image pickup sensor which is improved in spatial resolution and which is free from the influence of stray light.

In order to attain the above-mentioned object, according to the present invention, there is provided a back side incident type image pickup sensor having on the front side of a semiconductor substrate a photoelectric conversion portion and an electric circuit, and having on the back side of the semiconductor substrate an opening through which a light beam is let in to be detected by the photoelectric conversion portion formed on the front side of the semiconductor substrate, in which the electric circuit is placed to keep a given distance in the horizontal direction from the opening.

### BRIEF DESCRIPTION OF THE DRAWINGS

In the accompanying drawings:

FIG. 1 is a sectional view showing a first embodiment of a back side incident type image pickup sensor according to the present invention;

FIG. 2 is a sectional view showing a second embodiment of the present invention;

FIG. 3 is a diagram showing a third embodiment of the present invention;

FIG. 4 is a diagram showing a fourth embodiment of the present invention;

FIG. 5 is a graph showing an example of a spectral output characteristic of a back side incident type image pickup sensor; and

FIG. 6 is a diagram illustrating an optical characteristic at the interface between air and a semiconductor.

### DETAILED DESCRIPTION OF THE PREFERRED EMBODIMENTS

Embodiments of the present invention are described in detail below with reference to the drawings. Provided first by the present invention is a back side incident type image pickup sensor which avoids light of a certain wavelength that causes Problem (1) of conventional back side incident type image pickup sensors.

Light having a wavelength that makes a single crystal silicon substrate optically transparent is infrared light and X-rays, which are radiation rays. Far infrared light makes the substrate optically transparent in effect and the substrate also has a certain degree of transmittance for near infrared light.

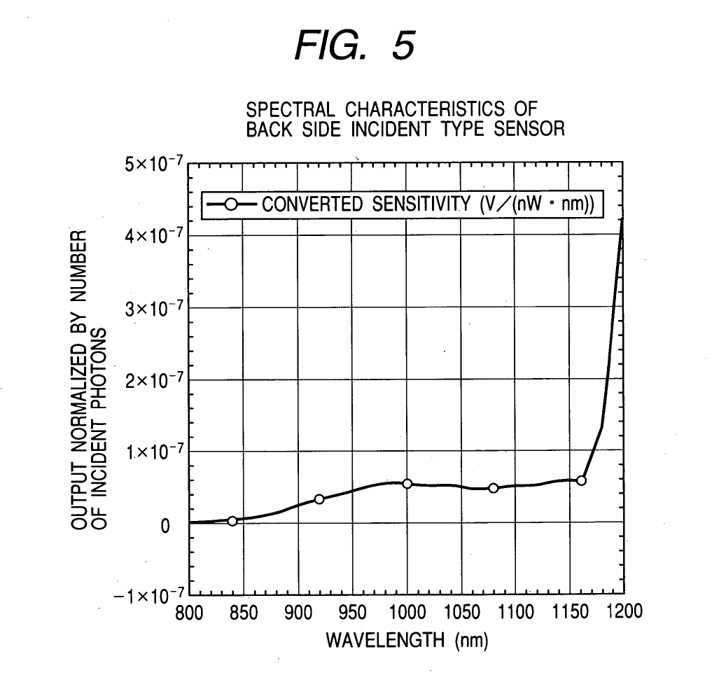

FIG. 5 shows an example of a spectral output characteristic of an actual back side incident type image pickup sensor which uses a CMOS sensor formed on a single crystal silicon substrate with a thickness of 100 μm. As is apparent from FIG. 5, infrared light is transmitted through the single crystal silicon substrate at an increasingly high transmittance as the wavelength of the infrared light approaches the band gap energy value (about 1.1 eV) of the substrate.

Inversely, detection of infrared light becomes harder and therefore the sensitivity of the sensor is lowered. The output characteristic obtained as a result is flat for a specific wavelength band, from 975 nm to 1150 nm, as shown in FIG. 5. It is therefore desirable to use an image pickup sensor in this range if the sensor has a substrate made of single crystal silicon.

A single crystal silicon substrate is also practically transparent to an X-ray which is a radiation ray. However, an X-ray which is one of radiation rays causes crystal defects in the substrate similar to other radiation rays and accordingly degrades electric characteristics of the image pickup sensor. For that reason, to use a material that has high specific gravity and density, such as lead glass for blocking radiation, in combination with a light-to-light conversion element is well known and practiced when using an image pickup sensor as an X-ray detection sensor.

When provided with such light-to-light conversion element and radiation blocking material, an image pickup sensor usually needs an intricate electric circuit formed on the front side of the substrate. Therefore the back side of the substrate which is flat and less sensitive because no intricate electric circuit is formed is in many cases superior to the front side of the substrate where the interface is irregular and sensitive. From this view point, back side incident type image pickup sensors could be used in detection of X-rays in a positive manner.

The present invention counters Problem (2) of the conventional back side incident type image pickup sensors with high refractive index of a semiconductor substrate and thinning of the substrate.

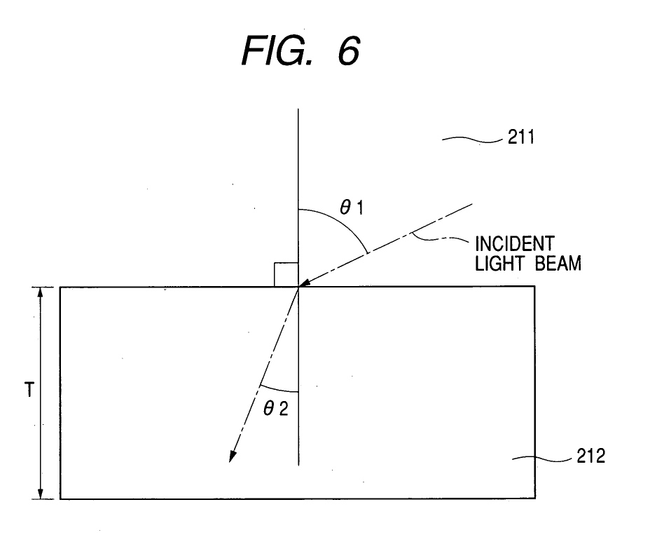

FIG. 6 is a diagram illustrating an optical characteristic of a light beam incident on a semiconductor substrate at an arbitrary angle θ1. In FIG. 6, reference numeral 211 denotes air and reference numeral 212 denotes the semiconductor substrate (single crystal silicon substrate).

The refractive index of the single crystal silicon substrate for a wavelength in the visible light range is about 3.448. Near infrared light enters the substrate from the air (atmosphere) side (refractive index: 1.0) at an angle θ2, which is expressed as follows:

sin θ2=sin θ1/3.448

Accordingly, sin θ2 is 0.290 at maximum and the angle θ2 is calculated as follows:

θ2=sin⁻¹ (0.290)=16.859°

Therefore light that enters silicon is completely contained in a cone with an apex angle of ±16.859°.

For instance, fingerprint sensors which are an application example of infrared sensors need a spatial resolution of about 800 dpi. To manufacture a back side incident type image pickup sensor that meets this requirement, usually a substrate with a thickness of 700 μm or more is thinned by known back grinding, back lapping, etching, or the like.

When a resolution pattern-in place of a fingerprint is put on the back side of a silicon substrate, which has been thinned to 100 μm, and is irradiated with diffused light having an incident angle of ±90°, light transmitted through the resolution pattern is diffused on the front side of the substrate to a distance corresponding to ±16.859°. The distance is given as d and is expressed as follows:

d=t×tan(16.859°)=t×0.303

The symbol t represents the thickness of the substrate and therefore the distance d is ±30.3 μm.

However, the pixel pitch in the pixel arrangement of 800 dpi is 31.75 μm and therefore scattered light that has been spread to ±30.3 μm only reaches adjacent pixels at most. From the above reasons, a fingerprint detection sensor having as high a resolution as 800 dpi can be obtained by thinning a substrate of the sensor.

Further, compared to the case of diffused light described above, an illumination LED for illuminating a finger and an element for light-to-light conversion of X-rays can provide a sharper image because the LED and the conversion element inherently emit highly directive light.

The present invention counters Problem (3) of the conventional back side incident type image pickup sensors regarding stray light with high refractive index of a semiconductor substrate, thinning of the substrate, an appropriate light-shielding structure, and an appropriate electric isolation structure.

For instance, when a fingerprint sensor utilizes outside light to illuminate a finger, there are some problems including high luminance solar light directly entering the sensor.

Direct sunlight has a luminance of about 10⁵ (lm/square meters). This is 10⁴ times higher than the luminance of the twilight, 10 (lm/square meters), which is the limit of a fingerprint sensor to pick up an image.

A fingerprint sensor has to cover such a wide image pickup range reaching 10⁴ and guarantee this dynamic range.

If direct sunlight enters other portions than a photoelectric conversion portion which serves as a light receiving portion, the intense light could cause malfunction of an electric circuit which constitutes the image pickup sensor. Accordingly, it is not safe to place the electric circuit in an area where such intense light enters from the back side.

An opening provided on the back side to determine the light incident region is formed by, for example, patterning of a member that blocks infrared light and removal of unnecessary portions. Incident light is spread approximately 0.303 times of the thickness of the substrate. Therefore, when a semiconductor substrate with a thickness of 100 μm is used for example, a driver circuit for driving a photoelectric conversion portion, a signal processing circuit for processing signals from the photoelectric conversion portion, and the like are each placed at least 30.3 μm away from the opening in the horizontal direction.

In back side incident type sensors, unlike front side incident type sensors, it is difficult to form a light-shielding film in front of a photodiode, namely, inside the semiconductor substrate. The back side incident type sensors therefore need an offset structure in which an electric circuit is kept at a given distance in the horizontal direction from the opening on the back side of the semiconductor substrate.

The offset portion is desirably provided with an electric isolation structure such as (1) an array of dummy pixels or (2) a structure that actively absorbs photocharges generated. This structure allows a fingerprint sensor to stably detect a fingerprint under direct sunlight having high luminance.

The above structure is also necessary in X-ray sensors where converted light from a light-to-light conversion element is present.

### FIRST EMBODIMENT

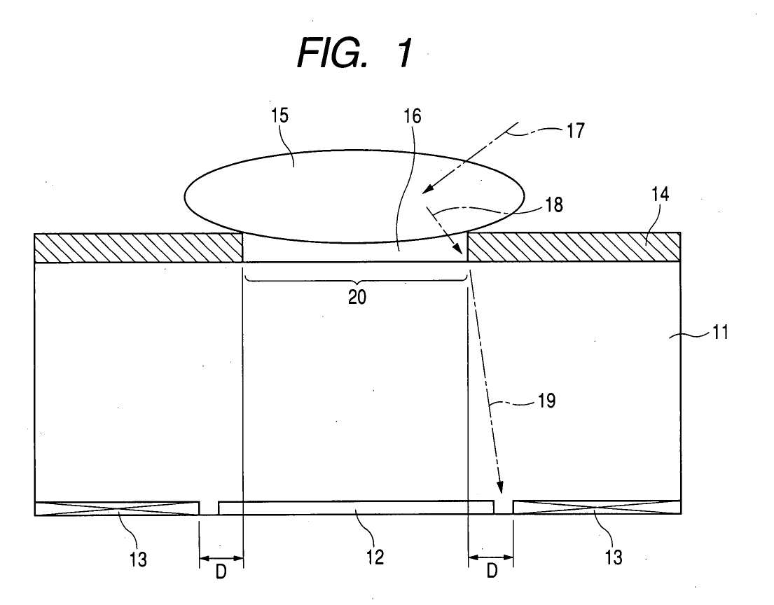

FIG. 1 is a sectional view showing a first embodiment of a back side incident type image pickup sensor according to the present invention. The back side incident type image pickup sensor of the first embodiment is used for fingerprint detection. In FIG. 1, reference numeral 11 denotes a 2 cm square single crystal silicon substrate that is thinned by back grinding to have a thickness of 100 μm after the image pickup sensor is formed by the usual semiconductor process.

A photoelectric conversion portion 12 of the image pickup sensor and other electric circuits 13 are formed on the front side of the single crystal silicon substrate 11. The electric circuits 13 include a driver circuit for driving the photoelectric conversion portion 12 and a signal processing circuit for processing signals from the photoelectric conversion portion 12.

A 2 mm thick light-shielding film 14 made of resin is formed on the back side of the single crystal silicon substrate 11 to block near infrared light. The light-shielding film 14 is patterned to have a 1 cm square opening 20 through which a light beam is let in as shown in FIG. 1.

A distance D in the horizontal direction between the opening 20 and each of the electric circuits 13 is 50 μm in this embodiment. A finger 15 from which a fingerprint is to be detected is placed on the light-shielding film 14. Air gaps 16 are created in some places between the finger 15 and the substrate 11 mainly by the fingerprint of the finger 15.

Denoted by reference numeral 17 is outside light containing near infrared light. In this embodiment, the outside light is utilized to illuminate the finger 15. Light 18 from the finger 15 is refracted at the interface between the air gaps 16 and the substrate 11 to enter the inside of the substrate and becomes incident light 19. The incident light 19 is in a cone having an apex angle of 16.859° as described above, and therefore travels no further than 100×tan(16.859°)=30.3 μm in the horizontal (lateral) direction from the opening 20 which is opened in the light-shielding film 14. This is shorter than the distance D, so that incident light does not reach the electric circuits 13 and accordingly does not cause malfunction.

The semiconductor substrate 11 used in the present invention may not necessarily be a single crystal silicon substrate and, for example, a Si—Ge substrate or other polycrystalline substrates can be employed. The thickness of the substrate 11 can be changed arbitrarily as long as image detection is possible. Thinning of the substrate 11 may be put before or after a dicing step in which the substrate 11 is cut into image pickup sensors.

In the case where the substrate 11 is too thin and lacks mechanical strength, an arbitrary material for enhancing the mechanical strength may be adhered to the front side or the back side of the substrate 11. Furthermore, the light-shielding film 14 may be a thin film of a metal or the like, and can have an arbitrary thickness. The presence of the air gaps 16 is not necessarily a structural requirement.

Here, the refractive index of a finger is 2 or less since it is close to the refractive index of water, which has higher ratio than any other component of a finger. The angle of light that exits the interface between the finger and the substrate is slightly larger than light that exits the interface between the air (atmosphere) and the substrate, but the influence is small compared to the thickness of the substrate 11.

If necessary, this problem can be dealt by giving a small margin to the distance D.

### SECOND EMBODIMENT

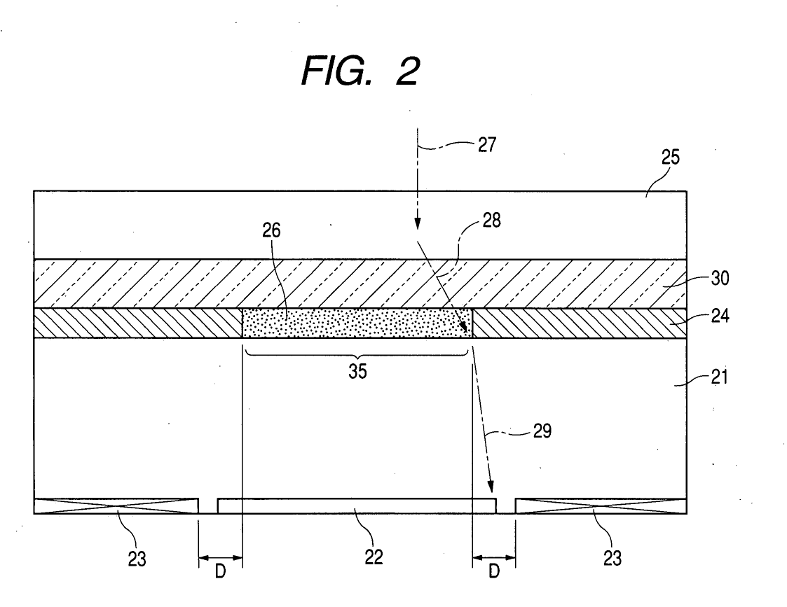

FIG. 2 is a sectional view showing a second embodiment of the present invention. This embodiment shows a back side incident type image pickup sensor for detecting an X-ray image. In FIG. 2, reference numeral 21 denotes a 4 cm square single crystal silicon substrate formed by etching to have a thickness of 50 μm. A photoelectric conversion portion 22 and other electric circuits 23 are formed on the front side of the single crystal silicon substrate 21 whereas a metal-made light-shielding film 24 with a thickness of 1 μm is formed on the back side of the substrate. A 3 cm square opening 35 is formed in the center of the light-shielding film 24. The electric circuits 23 include a driver circuit for driving the photoelectric conversion portion and a signal processing circuit for processing signals from the photoelectric conversion portion.

A distance D in the horizontal direction between the opening 35 and each of the electric circuits 23 is 50 μm in this embodiment. The back side of the silicon substrate 21 is bonded to a substrate 30 with an adhesive 26. The substrate 30 is a lead glass substrate having a thickness of 3 mm. A phosphor 25 to serve as a light-to-light conversion element for changing an X-ray into infrared light is applied to the top face of the substrate 30 to a thickness of 1 mm.

An X-ray 27 incident on this substrate is converted by the phosphor 25 into near infrared light 28 having a wavelength of 1 μm. The near infrared light 28 obtained by the conversion is transmitted through the lead glass 30 which is a radiation blocking film, and then enters the substrate 21 from the opening 35. The near infrared light 28 is refracted at the interface between the adhesive 26 and silicon of the substrate 21 to become near infrared light 29, which enters the photoelectric conversion portion 22. This way, the near infrared light 29 in this embodiment too is prevented from entering the electric circuits 23 because of the reasons described above.

Other than applying an adhesive in a usual manner, the anode junction method, for example, can be employed to bond the substrate 21 and the lead glass 30. In such case, the material of the metal light-shielding film has to be changed to an appropriate one. A light-to-light conversion element that converts an X-ray into far infrared light may be used instead of one that converts an X-ray into near infrared light. If more spatial resolution is needed, the lead glass may be replaced by a known FOP (fiber optical plate), for example.

### THIRD EMBODIMENT

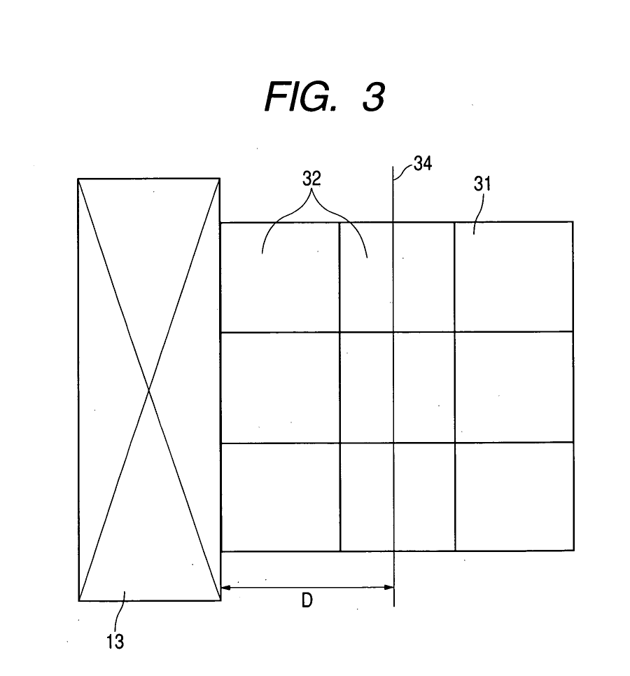

FIG. 3 is a diagram showing a back side incident type image pickup sensor according to a third embodiment of the present invention while focusing on a photoelectric conversion portion and a layout pattern of the periphery of the photoelectric conversion portion. The rest of the structure of this embodiment is similar to the one shown in FIG. 1. In FIG. 3, reference numeral 31 denotes 30 μm square unit pixels constituting the photoelectric conversion portion. The photoelectric conversion portion has 300 columns of pixels 31 by 300 rows of pixels 31, but only 3 columns×3 rows of pixels 31 are shown in FIG. 3. Denoted by reference numeral 34 is an opening pattern which defines a light beam incident on the photoelectric conversion portion. The opening pattern 34 corresponds to a point where a vertical line drawn down from an end of the opening 20 in FIG. 1 meets the photoelectric conversion portion.

Denoted by reference numeral 32 are dummy pixels and there are two columns by two rows of dummy pixels. The opening pattern 34 runs through the center of one of the dummy pixels 32 that is on the first column and the first row. One of the electric circuits 13, which include a driver circuit for driving the photoelectric conversion portion and a signal processing circuit for processing signals from the photoelectric conversion portion, is placed outside of one of the dummy pixels 32 that is on the second column and the second row. A horizontal distance D between the opening pattern 34 and each of the electric circuits 13 is 45 μm, which is equivalent to 1.5 pixels.

The substrate on which the image pickup sensor of this embodiment is formed has a thickness of 50 μm, and entering of near infrared light from the opening pattern 34 is limited within a range of 15.15 μm. Accordingly, infrared light that is refracted does not directly enter the electric circuits 13. This contains enough margin for light reflected by the surface structure disclosed in Japanese Patent Application Laid-Open No. 05-206432, which is mentioned in the above.

The dummy pixels are structured identically to normal pixels and the only difference between the two is that optical signals from the dummy pixels are not used as output information. Therefore, photocharges generated in the dummy pixels 32 by incident light can be absorbed without affecting the surroundings. Because of the dummy pixels, the electric circuits 13 are electrically isolated from the pixels 31 which receive incident light and malfunction of the electric circuits 13 is thus prevented.

### FOURTH EMBODIMENT

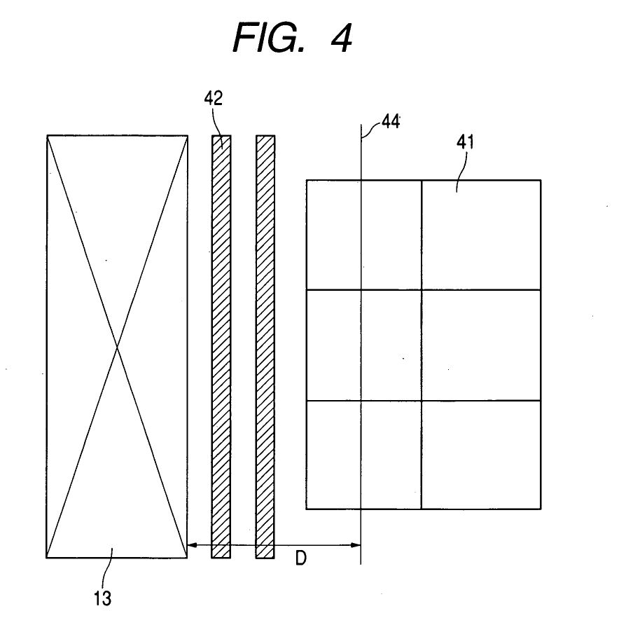

FIG. 4 is a diagram showing a back side incident type image pickup sensor according to a fourth embodiment of the present invention while focusing on a layout pattern of the periphery of a photoelectric conversion portion. The rest of the structure of this embodiment is similar to the one shown in FIG. 1. In FIG. 4, reference numeral 41 denotes 30 μm square unit pixels, and reference numeral 44 denotes an opening pattern. Denoted by reference numeral 13 are electric circuits which include a driver circuit for driving the photoelectric conversion portion and a signal processing circuit for processing signals from the photoelectric conversion portion, and which are placed in the periphery of the photoelectric conversion portion. The photoelectric conversion portion has 300 columns of pixels 41 by 300 rows of pixels 41, but only 2 columns×2 rows of pixels 41 are shown in FIG. 4. The opening pattern 44 corresponds to a point where a vertical line drawn down from an end of the opening 20 in FIG. 1 meets the photoelectric conversion portion. A distance D in the horizontal direction between the opening pattern 44 and each of the electric circuits 13 is 50 μm.

Denoted by reference numeral 42 denote P⁺ diffusion regions each having a width of 10 μm. The diffusion layers 42 are provided to establish an ohmic contact with a p type semiconductor substrate on which the image pickup sensor is formed and which has a thickness of 100 μm. The diffusion layers 42 are fixed at the GND electric potential, which is the lowest electric potential of the image pickup sensor.

In this embodiment, of electron-hole pairs which are photo carriers generated in the photoelectric conversion portion, the holes are absorbed through the diffusion layers 42 and do not reach the electric circuits 13. On the other hand, the electrons cannot approach the diffusion layers 42 because of the high potential barrier (GND electric potential) of the diffusion layers 42, and therefore are similarly prevented from reaching the electric circuits 13. This also protects the electric circuits 13 from incident light in the same manner.

As described above, according to the present invention, with the a back side incident type image pickup sensor, an excellent image less influenced by stray light is obtained without lowering the spatial resolution in a specific wavelength range where light is transmitted through the semiconductor substrate.

What is claimed is:

1. A back side incident type image pickup sensor having on the front side of a semiconductor substrate a photoelectric conversion portion and an electric circuit, and having on the back side of the semiconductor substrate an opening through which a radiation beam is incident, the incident radiation beam being detected by the photoelectric conversion portion formed on the front side of the semiconductor substrate, wherein the electric circuit is disposed at a given distance in the horizontal direction from the opening.

2. A back side incident type image pickup sensor according to claim 1, wherein the semiconductor substrate is a single crystal silicon substrate.

3. A back side incident type image pickup sensor according to claim 1, wherein the semiconductor substrate is reduced in thickness after a semiconductor integrated circuit that constitutes the photoelectric conversion portion is formed.

4. A back side incident type image pickup sensor according to claim 1, wherein the radiation beam is infrared light.

5. A back side incident type image pickup sensor according to claim 4, wherein the infrared light has a wavelength in a range of 975 to 1150 nm.

6. A back side incident type image pickup sensor according to claim 1, wherein the radiation beam is an X-ray.

7. A back side incident type image pickup sensor according to claim 1, wherein the photoelectric conversion portion is composed of a photodiode.

8. A back side incident type image pickup sensor according to claim 1, wherein the electric circuit serves as one of a driver circuit for driving the photoelectric conversion portion and a signal processing circuit for processing a signal from the photoelectric conversion portion.

9. A back side incident type image pickup sensor according to claim 1, wherein the given distance is 0.303 times the thickness of the semiconductor substrate or more.

10. A back side incident type image pickup sensor according to claim 1, wherein the given distance is 50 μm or more.

11. A back side incident type image pickup sensor according to claim 1, wherein a dummy pixel is formed in an offset portion between the electric circuit on the front side of the semiconductor substrate and the opening.

12. A back side incident type image pickup sensor according to claim 1, wherein a diffusion region for absorbing electric charges is formed in the offset portion between the electric circuit on the front side of the semiconductor substrate and the opening.
